(19) United States
(12) Patent Application Publication
(10) Pub. No.: US 2005/0140027 A1
(43) Pub. Date: Jun. 30, 2005

(54) Method and device for manufacturing bonding pads for chip scale packaging

(75) Inventor: Yuan-Heng Fan, Shanghai (CN)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Semiconductor Manufacturing International (Shanghai) Corporation, Shanghai (CN)

(21) Appl. No.: 10/773,800

(22) Filed: Feb. 6, 2004

(30) Foreign Application Priority Data
Dec. 30, 2003 (CN) 200310122967.9

(51) Int. Cl. H01L 21/44; H01L 23/48; H01L 23/52; H01L 29/40

(52) U.S. Cl. 257/779; 438/612

(57) ABSTRACT

An integrated circuit chip and method of manufacture. The chip has a substrate, e.g., silicon, silicon on insulator, epitaxial wafer. The substrate has a plurality of chip structures. A plurality of bonding pads are disposed on the substrate. Each of the bonding pads is formed from an aluminum bearing material or other like material. A surface region is formed on each of the bonding pads. An under bump metal layer (“UBM”) is overlying the surface region. A wetting layer is formed overlying the under bump metal layer. The wetting layer comprises a plurality of protrusions extending out of the wetting layer and disposed spatially on the wetting layer. A bump layer is formed overlying the wetting layer and is mechanically coupling to the plurality of protrusions.

### BACKGROUND OF THE INVENTION

The present invention is directed to integrated circuits and their packaging for the manufacture of semiconductor devices. More particularly, the invention provides a method for manufacturing a contact structure for packaging advanced integrated circuits such as microprocessors, application specific integrated circuits, memories, mixed signal applications, and the like. But it would be recognized that the invention has a much broader range of applicability.

Integrated circuits have evolved from a handful of interconnected devices fabricated on a single chip of silicon to millions of devices. Conventional integrated circuits provide performance and complexity far beyond what was originally imagined. In order to achieve improvements in complexity and circuit density (i.e., the number of devices capable of being parked onto a given chip area), the size of the smallest device feature, also known as the device “geometry”, has become smaller with each generation of integrated circuits.

Increasing circuit density has not only improved the complexity and performance of integrated circuits but has also provided lower cost parts to the consumer. An integrated circuit or chip fabrication facility can cost hundreds of millions, or even billions, of U.S. dollars. Each fabrication facility will have a certain throughput of wafers, and each wafer will have a certain number of integrated circuits on it. Therefore, by making the individual devices of an integrated circuit smaller, more devices may be fabricated on each wafer, thus increasing the output of the fabrication facility. Making devices smaller is very challenging, as each process used in integrated fabrication has a limit. That is to say, a given process typically only works down to a certain feature size, and then either the process or the device layout needs to be changed. Additionally, as devices require faster and faster designs, process limitations exist with certain conventional processes and materials and even packaging processes.

An example of such a process is the packaging of integrated circuit devices using solder bumps for chip scale packaging, commonly called CSP. Examples of CSP including, among others, Tape Carrier Package “TCP”, and Flip Chip. Although such packaging has certain benefits, many limitations still exist. Among these including poor reliability and yield loss. Further details of these limitations are described throughout the present specification and more particularly below.

From the above, it is seen that an improved technique for packaging semiconductor devices is desired.

### BRIEF SUMMARY OF THE INVENTION

According to the present invention, techniques for packaging integrated circuits for the manufacture of semiconductor devices are provided. More particularly, the invention provides a method for manufacturing a contact structure for packaging advanced integrated circuits such as microprocessors, application specific integrated circuits, memories, mixed signal applications, and the like. But it would be recognized that the invention has a much broader range of applicability.

In a specific embodiment, the invention provides an integrated circuit chip. The chip has a substrate, e.g., silicon, silicon on insulator, epitaxial wafer. The substrate has a plurality of chip structures. A plurality of bonding pads are disposed on the substrate. Each of the bonding pads is formed from an aluminum bearing material or other like material. A surface region is formed on each of the bonding pads. An under bump metal layer (“UBM”) is overlying the surface region. A wetting layer is formed overlying the under bump metal layer. The wetting layer comprises a plurality of protrusions extending out of the wetting layer and disposed spatially on the wetting layer. A bump layer is formed overlying the wetting layer and is mechanically coupling to the plurality of protrusions.

In an alternative specific embodiment, the invention provides a method for fabricating an integrated circuit chip. The method includes providing a substrate and forming a plurality of bonding pads overlying the substrate. Each of the bonding pads is formed from an aluminum bearing or like material, which has a surface region. The method also forms an under bump metal layer overlying the surface region and forms a wetting layer comprising a plurality of protrusions extending out of the wetting layer and is disposed spatially on the wetting layer. A bump layer is formed overlying the wetting layer and is mechanically coupling to the plurality of protrusions.

Many benefits are achieved by way of the present invention over conventional techniques. For example, the present technique provides an easy to use process that relies upon conventional technology. In some embodiments, the method provides higher device yields in packaged dies. Additionally, the method provides a process that is compatible with conventional process technology without substantial modifications to conventional equipment and processes. Preferably, the invention provides for an improved bump structure that is free from reliability and/or yield problems of conventional devices. Depending upon the embodiment, one or more of these benefits may be achieved. These and other benefits will be described in more throughout the present specification and more particularly below.

Various additional objects, features and advantages of the present invention can be more fully appreciated with reference to the detailed description and accompanying drawings that follow.

### BRIEF DESCRIPTION OF THE DRAWINGS

FIG. 1 is a simplified cross-sectional view diagram of an interconnect structure of conventional devices;

FIGS. 2 and 3 are simplified cross-sectional view diagrams of interconnect structures according to an embodiment of the present invention; and

FIGS. 4 through 8 illustrate a method for forming an interconnect structure according to an embodiment of the present invention.

### DETAILED DESCRIPTION OF THE INVENTION

According to the present invention, techniques for packaging integrated circuits for the manufacture of semiconductor devices are provided. More particularly, the invention provides a method for manufacturing a contact structure for packaging advanced integrated circuits such as microprocessors, application specific integrated circuits, memories, mixed signal applications, and the like. But it would be recognized that the invention has a much broader range of applicability.

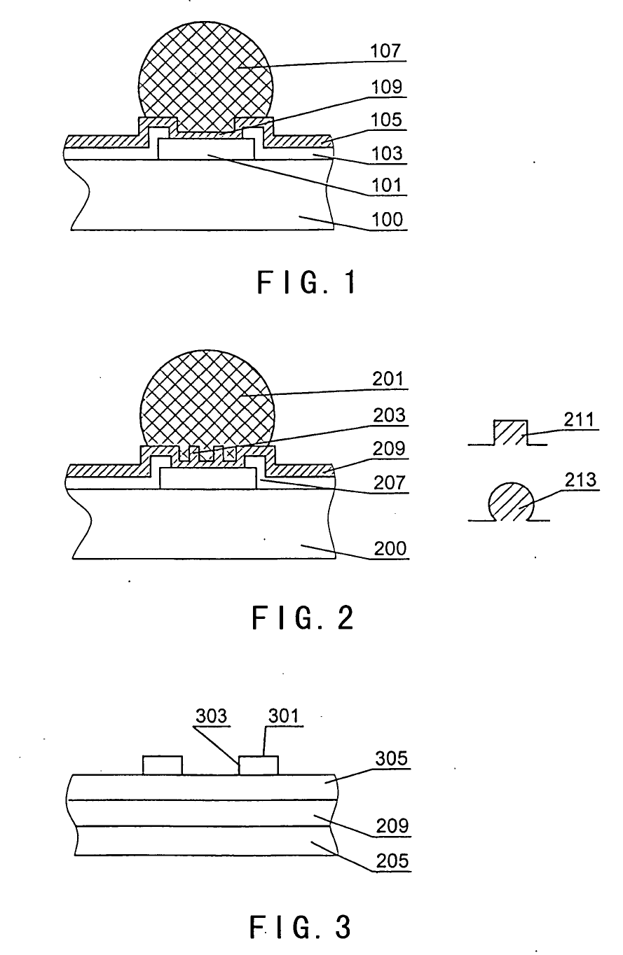

FIG. 1 is a simplified cross-sectional view diagram of an interconnect structure of conventional devices. As shown, the conventional device includes a substrate 100. A bonding pad 101 is disposed on the substrate. A passivation layer 103 overlies the substrate while maintaining an opening over a portion of the bonding pad. The structure also has an overlying UBM layer 105, which has a smooth surface overlying the bond pad. A bump layer 107 is formed overlying the UDP layer. Many limitations exist with this conventional structure. For example, the bump structure can often peel from the UDP layer, which leads to excess resistance and leads to reliability and/or operation problems. Additionally, during bump or solder reflow, bump layer often delaminates from the UDP layer. These and other limitations have been uncovered with the conventional devices.

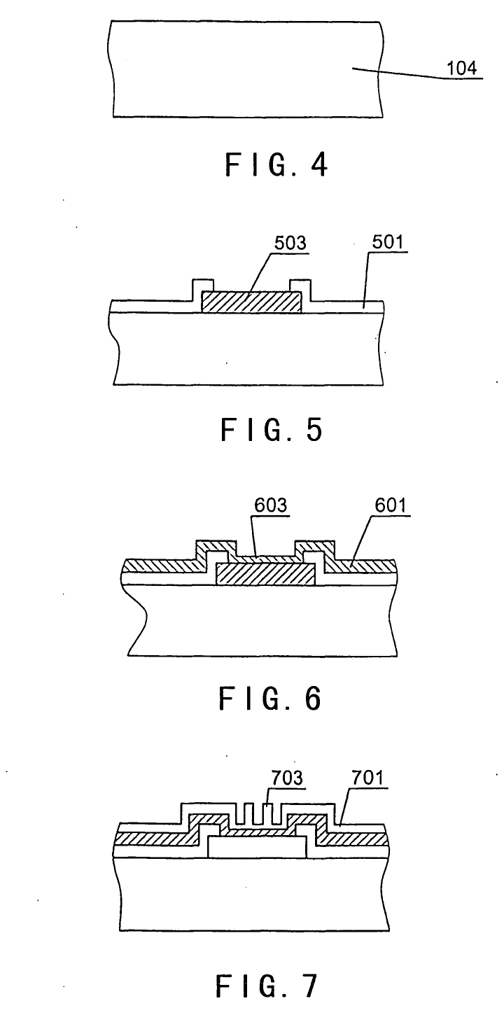

FIGS. 2 and 3 are simplified cross-sectional view diagrams of interconnect structures according to an embodiment of the present invention. As shown, the interconnect structure is on a substrate 100, e.g., silicon, silicon on insulator, epitaxial wafer. The substrate has a plurality of chip structures. A plurality of bonding pads 105 are disposed on the substrate. Each of the bonding pads is formed from an aluminum bearing material or other like material. A surface region is formed on each of the bonding pads. A passivation layer 207 is disposed overlying the substrate while maintaining an opening over a portion of the bond pad surface. An under bump metal layer (“UBM”) 209 is overlying the surface region. A wetting layer 203 is formed overlying the under bump metal layer. The wetting layer comprises a plurality of protrusions extending out of the wetting layer and disposed spatially on the wetting layer. A bump layer 201 is formed overlying the wetting layer and is mechanically coupled to the plurality of protrusions.

Depending upon the application, each of the protrusions can have a predetermined height and width. Each of the protrusions can also have a specific shape. Examples of shapes are shown by way of reference numerals 211 and 213. These shapes include rectangular and/or annular. The annular shape is hemispherical 213, which has a larger upper region and smaller lower region in a predefined configuration. Shape 213 serves as an anchor to hold bonding layer 201 onto the surface of the bonding pad. Referring to FIG. 3, each protrusion has a height 303 and width 301, which serves to anchor the bonding layer onto the wetting layer. Other layers shown include other portions of the wetting layer 305, UBM layer 209, and bonding layer 205. The wetting layer can be made of a suitable material such as nickel, platinum, copper, and molybdenum. Of course, the type of material used may depend upon the application. Further details of ways to manufacturing the present interconnect structure can be found throughout the present specification and more particularly below.

A method for fabricating an interconnect structure according to an embodiment of the present invention may be outlined as follows:
1. Provide a substrate;
2. Form a plurality of bonding pads overlying the substrate, where each of the bonding pads is formed from an aluminum bearing material and includes a surface region;
3. Form an under bump metal layer overlying the surface region;
4. Form a wetting layer overlying the under bump metal layer, Where the wetting layer comprises a plurality of protrusions extending out of the wetting layer and disposed spatially on the wetting layer; and
5. Form a bump layer overlying the wetting layer and mechanically coupling to the plurality of protrusions;
6. Perform other steps, as desired.

The above sequence of steps provides a method according to an embodiment of the present invention. As shown, the method uses a combination of steps including a way of forming an interconnect structure having an improved contact structure. Other alternatives can also be provided where steps are added, one or more steps are removed, or one or more steps are provided in a different sequence without departing from the scope of the claims herein. Further details of the present method can be found throughout the present specification and more particularly below.

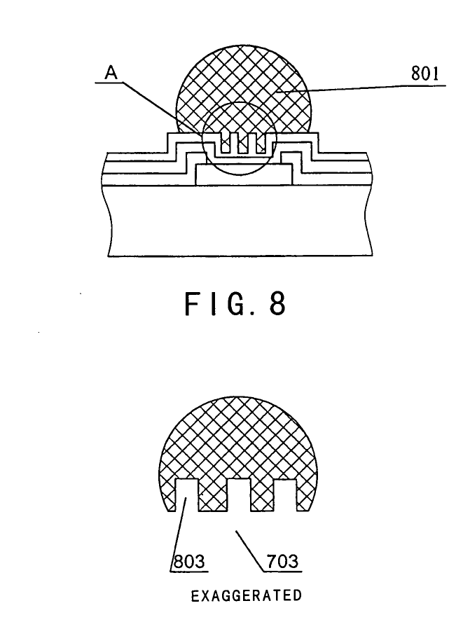

FIGS. 4 through 8 illustrate a method for forming an interconnect structure according to an embodiment of the present invention. These diagrams are merely examples, which should not unduly limit the scope of the claims herein. One of ordinary skill in the art would recognize many variations, alternatives, and modifications. As shown, the present method begins by providing a substrate 401, e.g., silicon substrate, silicon on insulator, epitaxial silicon. The substrates has an upper surface region and active devices thereon. The method includes forming a plurality of bonding pads 503 overlying the substrate. Each of the bonding pads is formed from an aluminum bearing material and/or other like material. Preferably, the bonding pad has a surface region, which has a certain size. The size may be 100 microns by 100 microns or 80 microns by 80 microns as well as others. The method forms a passivation layer 501 overlying portions of the substrate while exposing a portion of the surface of the bonding pad, as shown by FIG. 5.

Referring to FIG. 6, the method forms an under bump metal layer 601 overlying the surface region. The under bump metal layer is composed of an adhesive material, a protective material, and a wetting material. Examples of such materials include, among others, Ti, Cr, Ni, Cu, Mo, Pt, and Au. Depending upon the embodiment, other materials can also be used. As further shown, the under bump layer has surface region 603.

Next, the method forms a wetting layer 701 overlying the under bump metal layer, as illustrated by FIG. 7. The wetting layer comprises a plurality of protrusions extending out of the wetting layer and disposed spatially on the wetting layer. Depending upon the embodiment, the wetting layer can be formed using one of a plurality of techniques. For example, the wetting layer can be formed by depositing the wetting layer and then patterning the wetting layer to form the protrusions. Additionally, the wetting layer can be deposited with the protrusions by selective deposition techniques. Additionally, the wetting layer can be formed using any combination of etching and/or deposition techniques. These and other techniques would be recognized by one of ordinary skill in the art.

Referring to FIG. 8, the method also includes forming a bump layer 801 overlying the wetting layer. The bump layer also mechanically couples to the plurality of protrusions 803. The bump layer firmly attaches to the protrusions and does not delaminate or peel during a subsequent reflow or heat treatment process. Additionally, the bump layer is substantially free from reliability and/or yield related drawbacks of conventional devices.

It is also understood that the examples and embodiments described herein are for illustrative purposes only and that various modifications or changes in light thereof will be suggested to persons skilled in the art and are to be included within the spirit and purview of this application and scope of the appended claims.

1. An integrated circuit chip comprising:
a substrate, the substrates comprising a plurality of chip structures;
a plurality of bonding pads disposed on the substrate, each of the bonding pads being formed from an aluminum bearing material;
a surface region formed on each of the bonding pads;
an under bump metal layer overlying the surface region;
a wetting layer formed overlying the surface region, the wetting layer comprising a plurality of protrusions extending out of the wetting layer and disposed spatially on the wetting layer;
a bump layer overlying the wetting layer and mechanically coupling the plurality of protrusions.

2. The chip of claim 1 wherein the under bump metal comprises an adhesive material, a wetting material, and a protective material.

3. The chip of claim 1 wherein each of the protrusions has a predetermined height and a predtermined width.

4. The chip of claim 1 wherein each of the protrusions has a predetermined height, the height ranging from about 15 to about 20 microns.

5. The chip of claim 1 wherein each of the bonding pads has a dimension of about 80 microns by about 80 microns.

6. The chip of claim 1 wherein the wetting layer is provided by a deposition or plating process.

7. The chip of claim 1 wherein the plurality of protrusions prevents a possibility of the bump layer from peeling from the surface region of the bonding pad.

8. The chip of claim 1 wherein the plurality of protrusions prevents a possibility of the bump layer from peeling from the surface region during a reflow process.

9. The chip of claim 1 wherein the substrate comprises silicon.

10. The chip of claim 1 wherein the substrate is a silicon on insulator wafer.

11. A method for fabricating an integrated circuit chip comprising:
providing a substrate;
forming a plurality of bonding pads overlying the substrate, each of the bonding pads being formed from an aluminum bearing material and including a surface region;
forming an under bump metal layer overlying the surface region;
forming a wetting layer overlying the under bump metal layer, the wetting layer comprising a plurality of protrusions extending out of the wetting layer and disposed spatially on the wetting layer; and
forming a bump layer overlying the wetting layer and mechanically coupling to the plurality of protrusions.

12. The method of claim 11 wherein the under bump metrology comprises an adhesive material, a wetting material, and a protective material.

13. The method of claim 11 wherein each of the protrusions has a predetermined height and a predtermined width.

14. The method of claim 11 wherein each of the protrusions has a predetermined height, the height ranging from about 15 to about 20 microns.

15. The method of claim 11 wherein each of the bonding pads has a dimension of about 80 microns by about 80 microns.

16. The method of claim 11 wherein the wetting layer is provided by a deposition or plating process.

17. The method of claim 11 wherein the plurality of protrusions prevents a possibility of the bump layer from peeling from the surface region of the bonding pad.

18. The method of claim 11 further comprising reflowing the bump layer while maintaining the bump layer on the surface region through the plurality of protrusions.
